(19) United States
(12) Patent Application Publication
(10) Pub. No.: US 2023/0268233 A1
(43) Pub. Date: Aug. 24, 2023

(54) Laser Spike Annealing Process Temperature Calibration Utilizing Photoluminescence Measurements

(71) Applicant: Veeco Instruments Inc., Plainview, NY (US)

(72) Inventor: Nardeep Kumar, Fremont, CA (US)

(21) Appl. No.: 18/107,870

(22) Filed: Feb. 9, 2023

Related U.S. Application Data
(60) Provisional application No. 63/268,242, filed on Feb. 18, 2022.

(51) Int. Cl. H01L 21/66; H01L 21/324

(52) U.S. Cl. CPC H01L 22/14; H01L 22/20; H01L 21/324

(57) ABSTRACT

Temperature measurement techniques for device structures formed from detectable bandgap semiconducting materials based on photoluminescence (PL) spectroscopy. Laser annealing temperature calibrations for process temperature control are derived from PL measurements and the derived laser annealing temperature calibrations are implemented in process controllers of laser annealing systems to control an operating parameter of an annealing laser.

### RELATED APPLICATION DATA

This application claims the benefit of priority of U.S. Provisional Patent Application Ser. No. 63/268,242, filed Feb. 18, 2022, and titled “Laser Spike Annealing Process Temperature Calibration Utilizing Photoluminescence Measurements,” which is incorporated by reference herein in its entirety

### FIELD OF THE DISCLOSURE

The present disclosure generally relates to the field of semiconductor processing. In particular, the present disclosure is directed to laser spike annealing process temperature calibration utilizing photoluminescence measurements.

### BACKGROUND

Integrated electronic components are fabricated on thin semiconductor wafers using various materials with silicon being the primary material. One of the most critical parameters for the many device fabrication processes is the process temperature control. To get better control on the process temperature it is important to accurately measure the local temperature in-situ. Regular thermocouples are still under use in many semiconductor applications, however, thermocouples suffer from a limitation of response time, inaccuracy, drift over time, and signal nonlinearity rendering them inadequate for fast thermal annealing processes, such as laser spike annealing (LSA), which includes scanning a laser beam over a small area of the wafer in nanoseconds or microseconds. For fast thermal annealing processes, the process temperature should be measured locally within the laser stripe or image on the wafer surface. Existing non-contact temperature measurement techniques include thermo-reflection, transmittance, light interference, and thermal emission.

### SUMMARY OF THE DISCLOSURE

In one implementation, the present disclosure is directed to a method of determining a relationship between a photoluminescence (PL) spectra and a material temperature of a semiconductor material. The method includes heating the semiconductor material to a plurality of temperatures; exciting a PL response from the semiconductor material with an excitation source; determining a PL characteristic from a PL signal emitted from the semiconductor material; determining a relationship between a power level of the excitation source and the determined PL characteristic at each of the plurality of temperatures; extrapolating the determined relationships to identify extrapolated PL characteristics for each of the plurality of temperatures at a zero power level condition of the excitation source to eliminate a local heating influence of the excitation source on the PL characteristic; and deriving a PL characteristic-material temperature relationship from the plurality of extrapolated PL characteristics.

In another implementation, the present disclosure is directed to a method of determining a laser annealing temperature calibration for process temperature control. The method includes receiving a photoluminescence (PL) characteristic-material temperature relationship for a semiconductor material; measuring a PL characteristic during a laser annealing process of the semiconductor material at a plurality of annealing laser power levels; and determining at least one laser annealing temperature calibration from the measured PL characteristics and the received PL characteristic-material temperature relationship.

In yet another implementation, the present disclosure is directed to a method for controlling an annealing laser operating parameter during a laser annealing process. The method includes selecting, accessing, or receiving a laser annealing temperature calibration; and controlling an operating parameter of an annealing laser during an annealing process of a semiconductor material according to a target annealing process temperature and the laser annealing temperature calibration; wherein the laser annealing temperature calibration is a correlation between the annealing laser operating parameter and an in-situ local temperature of the semiconductor material under a predetermined set of annealing process conditions, wherein the correlation was derived from photoluminescence measurements of the semiconductor material during a laser annealing process of the semiconductor material.

In yet another implementation, the present disclosure is directed to a method of calibrating an annealing process temperature in a laser annealing system that includes a first laser and an annealing laser. The method includes forming an annealing image on a region of a semiconductor material with the annealing laser; optically exciting the region of the semiconductor material with the first laser to emit photoluminescence (PL) from the semiconductor material; and spectrally resolving the PL to identify a PL characteristic that is dependent on a bandgap of the semiconductor material.

In yet another implementation, the present disclosure is directed to a laser annealing system. The laser annealing system includes a preheat laser; an annealing laser; a storage device containing at least one laser annealing temperature calibration that provides a correlation between an operating parameter of the annealing laser and an in-situ local temperature of a semiconductor material under a predetermined set of annealing process conditions, wherein the correlation was derived from photoluminescence measurements of the semiconductor material during a laser annealing process of the semiconductor material; and a process controller configured to control the annealing laser according to an annealing process temperature and the at least one laser annealing temperature calibration.

In yet another implementation, the present disclosure is directed to a non-transitory machine readable storage medium. The non-transitory machine readable storage medium includes at least one laser annealing temperature calibration that provides a correlation between an operating parameter of the annealing laser and an in-situ local temperature of a semiconductor material under a predetermined set of annealing process conditions, wherein the correlation was derived from photoluminescence measurements of the semiconductor material during a laser annealing process of the semiconductor material.

### BRIEF DESCRIPTION OF THE DRAWINGS

For the purpose of illustrating the disclosure, the drawings show aspects of one or more embodiments of the disclosure. However, it should be understood that the present disclosure is not limited to the precise arrangements and instrumentalities shown in the drawings, wherein:

FIG. 1 is a schematic diagram of a dual-wavelength laser spike annealing system made in accordance with the principles of the present disclosure;

FIG. 2 is a graph showing PL spectra obtained from a semiconductor material, here a crystalline Si wafer, with the system of FIG. 1 at various chuck temperatures;

FIG. 3 is a graph showing PL peak wavelength versus preheat laser power curves obtained from a Si wafer at different chuck temperatures ranging from 150° C. to 350° C. Each curve is linearly fitted using least squares method;

FIG. 4 is a graph showing determined slope and intercept coefficients, using least squares fitting, to be used for dual-wavelength laser spike annealing temperature calibrations;

FIG. 5 is a graph showing PL spectra obtained from the Si wafer at various annealing laser powers at a chuck temperature of 150° C.;

FIG. 6 is a graph showing calibrated dual-wavelength laser spike annealing temperatures obtained from the Si wafer at various annealing laser powers at a chuck temperature of 150° C.;

FIG. 7 is a flow chart illustrating an example method of developing photoluminescence-material temperature relationships for a semiconductor material;

FIG. 8 is a flow chart illustrating an example method of determining laser annealing temperature calibration for process temperature control during a laser annealing process;

FIG. 9 is a flow chart illustrating an example method of controlling an operating parameter, such as power level, of an annealing laser during an annealing process; and

FIG. 10 is a functional block diagram of an example computing device.

### DETAILED DESCRIPTION

Aspects of the present disclosure include temperature measurement techniques for device structures formed from detectable bandgap semiconducting materials based on photoluminescence (PL) spectroscopy. Laser annealing temperature calibrations for process temperature control are derived from PL measurements and the derived laser annealing temperature calibrations are implemented in process controllers of laser annealing systems to control an operating parameter of an annealing laser. In some examples, the laser annealing temperature calibrations are low temperature or below melt (below the melting point of the material) calibrations for annealing operations below about 1,000° C.

Throughout the present disclosure, unless otherwise specified, the term “about” when used with a corresponding numeric value may refer to ±20% of the numeric value, or may refer to ±10% of the numeric value, or may refer to ±5% of the numeric value, or may refer to ±2% of the numeric value. In some examples, the term “about” may mean the numeric value itself.

Aspects of the present disclosure include methods for measuring the in-situ process temperature for a semiconductor laser annealing process. An excitation source can be imaged on a region of interest of the semiconductor that causes charge carriers in the valence band to be optically excited to the conduction band, resulting in photoluminescence (PL) emission during the recombination mechanism. The peak wavelength of the emitted PL indicates the bandgap of the semiconductor. According to Y. P. Varshni, Physica 39, 149 (1967) the bandgap of semiconductors E_{g}(T) depends upon temperature with following empirical relation:

E_{g}(T)=E_{g}(0)−αT²/β+T Equation 1

where E_{g}(0) is the energy gap or bandgap at zero temperature with α and β are empirical parameters. Without limiting the present disclosure to a particular theory, the cause of the temperature-dependence of the bandgap of a semiconductor in a given case may be related to a lattice dilation contribution to the temperature dependence changes of the conduction and valence bands and/or a temperature-dependent electron-phonon interaction.

The empirical relationship disclosed in Varshni has been tested by some groups and shows a non-linear character in lower temperature regions, about from −223° C. to 130° C. See, e.g., N. W. Ashcroft and N. D. Mermin, Solid State Physics (Holt, Rinehart and Winston, New York, 1976); J. I. Pankove, Optical Processes in Semiconductors (Prentice-Hall, Englewood Cliffs, N.J., 1971); M. B. Panish and H. C. Casey, Jr., J. Appl. Phys. 40, 163 (1969); B. S. Sahu, F. Delachat, A. Slaoui, M. Carrada, G. Ferblantier and D. Muller, Nanoscale Res. Lett. 6, 178 (2011); C. Mo, L. Zhang, C. Xie, and T. Wang, J. Appl. Phys. 73, 5185 (1993). The present inventors have found, however, that above about 300° C. the PL response of semiconductors, such as crystalline Si, is not well explored. The present paper discloses techniques for utilizing PL spectroscopy for laser annealing process temperature control for the annealing of semiconductor materials, including both direct bandgap and indirect bandgap semiconductor materials.

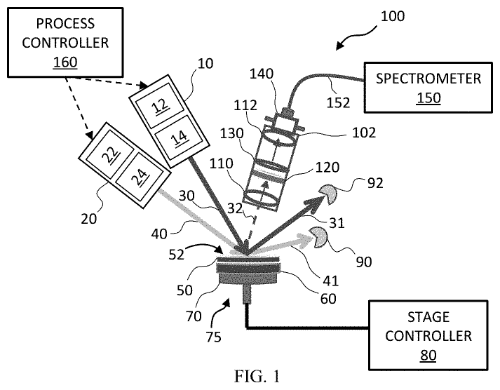

FIG. 1 illustrates an example implementation of the present disclosure in the form of a dual-wavelength laser spike annealing (LSA) system 100 with an excitation source 10 configured to be imaged on a wafer 50 and generate free carriers in the wafer that results in a PL signal 32, where the PL signal is the photons emitted by the wafer material as a result of the PL response of the material to the excitation source. System 100 also includes an annealing laser system 20 configured to perform a laser annealing process, such as a laser spike annealing process. Wafer 50 is disposed on a wafer chuck 60 that is connected to a chuck heater 70 which in turn is connected to motor driven stage 75 which can move in one or two directions with the help of stage controller 80. In the illustrated example, excitation source 10 is a laser that is configured to emit a focused continuous wave (CW) beam 30 to optically excite the wafer 50 to cause charge carriers to move across the bandgap of the wafer material due to the photons of the laser beam having a larger energy than the bandgap energy of the wafer material.

Excitation source 10 may be selected according to known principles of PL spectroscopy and according to the type of wafer material. In the illustrated example, excitation source 10 is selected for a Si wafer and includes a diode laser 12 and optical components 14 that generates a CW beam 30 with a wavelength in the near infrared wavelength range, i.e. about 750 nm to about 1.4 μm and in some examples a wavelength in the range of 808 nm to 1 μm with photons having an energy that is greater than the bandgap energy if Si, e.g., an energy greater than about >1.4 eV. In other examples, other laser types, such as other diode lasers, a fiber laser or a CO2 laser may be used. In the illustrated example, excitation source 10 is also designed and configured to be a preheat laser that is used in conjunction with annealing laser system 20 to perform a LSA process. Optical components 14 are configured to form a preheat line image on wafer surface 52. In other words, in the illustrated example, a preheat laser (excitation source 10) of system 100 is being utilized as an excitation source for PL for performing a PL spectroscopy measurement.

In the illustrated example, annealing laser system 20 includes a CW CO2 laser 22 and optical components 24 configured to generate a focused CW beam 40 with a long infrared wavelength, e.g. in the range of about 8 μm to about 15 μm, and in some examples, 10.6 μm, for annealing the wafer 50. Optical components 14 and 24 can each include lenses, mirrors, apertures, filters, active optical elements (e.g., variable attenuators, etc.) and combinations thereof. In an example, one or both of optical components 14 and 24 can be configured to perform beam conditioning, e.g., uniformize their respective laser beams 30 and 40 and/or provide the laser beams with a select cross-sectional shape. Example optical systems suitable for performing such beam conditioning are disclosed in U.S. Pat. Nos. 7,514,305, 7,494,942, 7,399,945 and 6,366,308 the contents of which are incorporated by reference herein in their entireties. In an example, optical components 24 are configured to form an annealing image on the wafer surface 52 that overlaps the preheat line image formed by excitation source 10 in a scanning overlap region where the two laser systems 10 and 20 work in conjunction to perform an annealing process as is known in the art of dual wavelength laser spike annealing. Optical components 14 and/or optical components 24, in conjunction with stage 75 and stage controller 80 are configured to selectively and rapidly move the scanning overlap region across the wafer surface 52. The location and speed of the scanning overlap region with respect to the wafer surface and the resulting dwell time of the scanning overlap region over a given area of the wafer surface can be varied for particular LSA process conditions. Dwell times can range from on the order of 10 ns up to hundreds of μs, e.g. 500 μs. First reflected laser beam 31 and second reflected laser beam 41 from the wafer 50 are collected by water cooled metallic beam dumps 90 and 92 respectively. Examples of laser spike annealing systems are described in U.S. Pat. No. 10,083,843, titled, Laser Annealing Systems And Methods With Ultra-Short Dwell Times, the contents of which are incorporated by reference herein in its entirety.

Incident photons from excitation source 10 excite the surface of wafer 50 to emit PL signal 32. In turn, the PL signal 32 from wafer surface 52 is collected by an objective microscope 102 which, in the illustrated example, includes two standard lenses 110 and 112 and an optical filter 120 and a polarizer 130. Optical components of the objective microscope 102, including the illustrated lenses 110 and 112 and optical filter 120, may be selected according to the characteristics of PL signal 32 and LSA process conditions. For example, PL signal 32 for Si has wavelength ranges in the IR spectrum of about 1100 nm to about 1500 nm and so objective microscope 102 may be designed with optical components for imaging that spectral range or be designed for a different range when working with a material other than Si that emits a PL signal at a different wavelength range. In an example, polarizer 130 is a linear polarizer and may be included to increase the PL signal relative to noise for a given set of LSA process conditions. In an example, the PL signal is not polarized and is not influenced by the polarizer, whereas the beams 30 and 40 in an example are polarized and the polarizer 130 filters stray photons from beams 30, 40, 31, or 41 from reaching spectrometer 150.

Element 140 in an example is an X-Y translation stage with focus adjustment components and is configured to move the microscope 102 in one or two directions to image an area of interest of the wafer surface where the PL signal is being emitted from. In one example, a field of view (FOV) of microscope 102 is designed and configured to have a size that is greater than a size of the scanning overlap region of the overlapping images formed by excitation source 10 and annealing laser system 20 on wafer surface 52 and the microscope is configured for the FOV of the microscope to include the scanning overlap region, for example, for the scanning overlap region to be substantially centered in the FOV. The PL signal 32 collected by microscope 102 is directed to a spectrometer 150, for example, an infrared spectrometer, through optical, low-OH multimode, fiber 152. Spectrometer 150 is configured to provide a spectral analysis of the PL signal 32 to identify one or more characteristics of the PL signal at various LSA process conditions as described herein. Process controller 160 is coupled to and controls excitation source 10 and annealing laser 20.

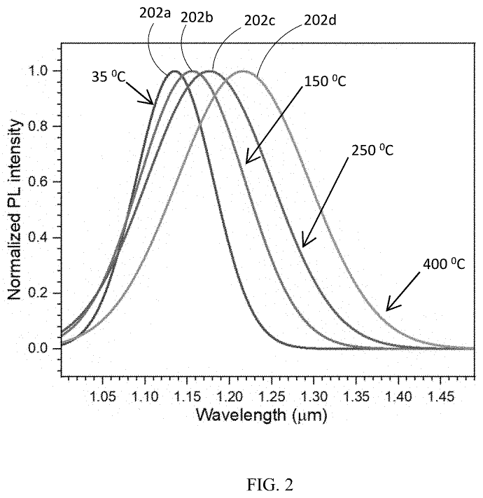

FIG. 2 shows an example of PL spectra collected by microscope 102 and analyzed by spectrometer 150 from wafer 50 in an example where the wafer is crystalline Si. FIG. 2 illustrates normalized PL intensity on the Y-axis and the wavelength of the PL signal 32 along the X-axis. FIG. 2 shows PL spectra at various temperatures of chuck 60 (chuck temperatures). The PL spectra was collected by using excitation source 10 to excite PL from the wafer 50 with the excitation source operating at a first steady state power level, for example, about 12 W of power. For the sake of illustration, spectra are conceptually shown in FIG. 2 for only four chuck temperatures: 35° C., 150° C., 250° C. and 400° C. In the illustrated example, chuck heater 70 was used to heat the chuck 60 to the indicated steady state temperature, thereby also heating the wafer 50 disposed on the chuck, the wafer allowed to achieve a uniform steady state temperature. Secondary temperature measurements, such as conventional contact (e.g. thermocouple) (not illustrated) and non-contact (e.g. pyrometer) (not illustrated) may be used to confirm the temperature of the wafer 50. As indicated in FIG. 2, the detected PL characteristics of wafer 50 has a temperature dependency as predicted by Equation 1, with the detected PL peaks 202a-202d for the Si wafer 50 shifting to longer wavelengths with increasing temperature. As described more below, this temperature dependency may be utilized to accurately control the power levels of annealing laser 20 during an annealing process to achieve a desired annealing temperature of the wafer. The spectrums in FIG. 2 were generated by near-infrared spectrometer 150 which collect the light from a wafer surface 52 through objective microscope 102 and optical fiber 152, digitize the PL signal 32 as a function of wavelength after splitting the signal into its spectral units before outputting the spectral data as is known in the art of spectrometry.

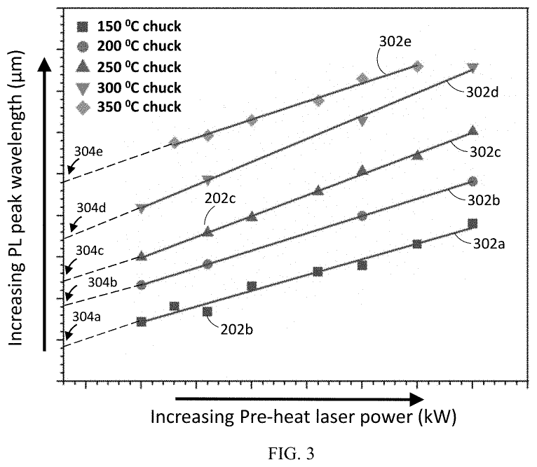

FIG. 3 illustrates PL peak wavelengths 202 (only two labeled) determined from PL spectra using excitation source 10 while operating the excitation source 10 at a plurality of power levels and chuck heater 70 at a plurality of chuck temperatures. As with the data shown in FIG. 2, the datapoints in FIG. 3 were obtained by allowing the global temperature of the wafer 50 to reach a steady state condition that equaled the chuck temperature such that the global temperature of the wafter was known and the same as the indicated chuck temperature. FIG. 3 shows PL peak wavelength along the Y-axis and excitation source power level along the X-axis. As with FIG. 2, FIG. 3 shows the PL peak wavelength increases with increasing chuck (and wafer) temperature. FIG. 3 also shows the PL peak wavelength increases with increasing power level of the excitation source 10. The increase in PL peak wavelength with excitation source power level is due to the beam 30 of excitation source 10 heating a local area of the wafer 50 where the beam is being imaged on the wafer (also referred to herein as the preheat line image) thereby causing the local wafer temperature to be higher than the chuck temperature and corresponding global wafer temperature. FIG. 3 shows a substantially linear relationship between PL peak wavelength and excitation source power level. In FIG. 3, a least squares fitting method was utilized to obtain PL peak wavelength versus excitation source power curves 302a-302e from the PL characteristic (peak wavelength) test data.

In one example, the PL peak wavelength versus excitation source power curves 302 are linear and may be described by the general linear equation of Y=m*X+b. The relationship between a PL characteristic and a wafer temperature, e.g., a relationship between a PL peak wavelength and wafer temperature, may be determined by extrapolating the PL peak wavelength versus excitation source power level curves 302 to identify Y-axis intercepts 304a-304e of the curves representing an excitation source power level of OW. In one example, the Y-axis intercepts 304 are the value corresponding to “b” in the linear equation describing the relationship between PL peak wavelength and excitation source power (e.g., curves 302). In other words, the curves 302 may be extrapolated to factor out the local heating influence of the beam 30 of excitation source 10 from the determined PL characteristic-wafer temperature relationship.

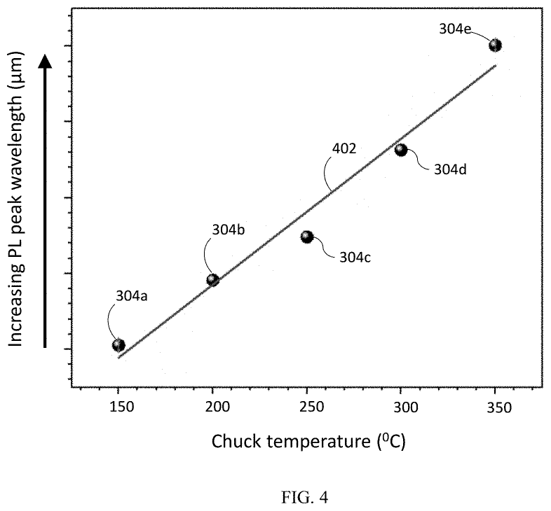

FIG. 4 shows the Y-axis intercepts 304 from FIG. 3, with PL peak wavelength along the Y-axis and chuck temperature along the X-axis. FIG. 4 also shows a curve 402 obtained by, for example, a least squares fitting method, of the Y-axis intercepts 304. FIG. 4 shows that for the illustrated semiconductor wafer material, here crystalline Si, there is a linear relationship between PL peak wavelength and wafer temperature over the illustrated temperature range, here 150° C.-350° C. Further, by eliminating the local heating influence of the excitation source by utilizing the Y-axis intercepts 304, the global wafer temperature can be plotted against PL peak to derive curve 402 representing the actual PL peak-wafer temperature relationship. Curve 402 may, therefore be utilized to independently and accurately determine the actual local wafer temperature during an annealing process from a measured PL spectra.

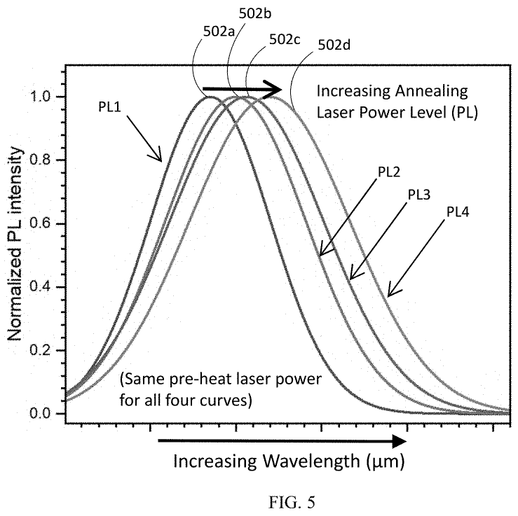

FIG. 5 illustrates test data from an example wafer annealing process utilizing LSA system 100 (FIG. 1), where excitation source 10 is a preheat laser of the LSA system. The test data illustrated in FIG. 5 were obtained while operating the system 100 at a set of pre-defined LSA process conditions, which may include a predefined chuck temperature, dwell time, stage speed, and preheat laser power. For example, to obtain the spectral data illustrated in FIG. 5, stage controller 80 may be utilized to operate stage controller 80 in conjunction with optical components 14 and/or 24 to move the scanning overlap region at a predefined speed and pattern, e.g. a raster pattern, resulting in a particular dwell time of the scanning overlap region on the wafer surface. Excitation source 10 may be utilized as a preheat laser and operated at a preheat laser power that will be utilized during a LSA process. For example, FIG. 5 shows test data from operating excitation source 10 as a preheat laser at 0.25 kW. In the illustrated example, chuck heater 70 was set at 150° C. In the illustrated example, the preheat laser of system 100 was, therefore, simultaneously utilized to preheat the wafer according to known dual-wavelength laser spike annealing processes and also utilized as the excitation source 10 for exciting PL for deriving an annealing laser power-wafer temperature relationship. In other examples, the preheat laser and the excitation source 10 may be separate components. In yet other examples, an annealing laser power level-wafer temperature calibration curve may be developed for laser annealing processes that do not utilize a preheat laser.

PL signals 32 may be captured by microscope 102 at a given power level of the annealing laser system 20 and the test may be repeated at various annealing laser power levels. FIG. 5 conceptually illustrates PL spectra at four power levels of the annealing laser system 20, here 0 kW-2 kW, showing the PL peak wavelengths 502a-502d increasing with increasing annealing laser power level. The PL peak increases with annealing laser power level due to an increased local wafer temperature caused by increased heating of the wafer by the annealing laser at higher power levels.

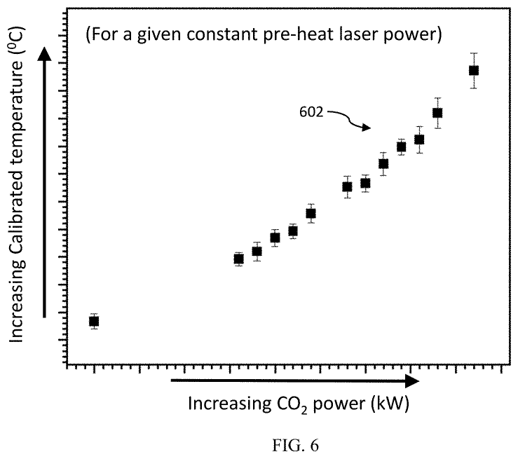

The data illustrated in FIG. 5 may then be utilized along with a predetermined PL spectra-wafer temperature relationship (e.g. PL peak-temperature curve 402) to derive a laser annealing temperature calibration that directly relates the annealing laser power level (and/or other operating parameters of the annealing laser) to the local wafer temperature. The laser annealing temperature calibration can provide a correlation between the annealing laser power level and an in-situ local temperature of the semiconductor material during a laser annealing process under a plurality of predetermined annealing process conditions. FIG. 6 illustrates one example of a laser annealing temperature calibration curve 602 that was derived from PL peak wavelengths 502 (FIG. 5) and PL peak-temperature curve 402 (FIG. 4). By utilizing the predetermined relationship between the PL spectra and the temperature of the wafer material (e.g., PL peak-temperature curve 402), the actual instantaneous local wafer temperature during a set of predefined annealing process conditions can be directly calculated from spectral measurements of the PL signal 32. Calibration curve 602 provides a relationship between annealing laser power level and wafer temperature for a set of predefined annealing process conditions that were in place when the data for the calibration curve was collected. The set of predefined annealing process conditions include one or more of speed of the stage 75 (stage speed), dwell time of the annealing laser image on the wafer surface, chuck temperature, and/or preheat laser power (in applications where both a preheat laser and annealing laser are utilized). Calibration curve 602 or other calibration data derived therefrom, such as a lookup table, can then be used during an annealing process, such as an LSA process. The laser annealing temperature calibration can be used to tightly control the process temperature by controlling the annealing laser power level (and/or other operating parameters of the annealing laser other than power level) for a desired wafer temperature according to the calibration information.

The exemplary test data illustrated in FIGS. 2-6 was obtained from a crystalline Si wafer, however, the teachings of the present disclosure may be utilized for any of a variety of other direct or indirect bandgap semiconducting materials, such as gallium antimonide, gallium arsenide, and indium phosphide, among others presently known in the art or later developed. Moreover, in the illustrated example, the PL characteristic utilized was PL peak wavelength, however, as will be appreciated by persons of ordinary skill in the art after reading the entire present disclosure, the temperature-dependency of other PL spectra characteristics may also be utilized to develop laser annealing temperature calibrations. Non-limiting examples of PL spectra characteristics include PL intensity and PL FWHM (full width at half maximum), which may be utilized instead of or in addition to PL peak wavelength, for example, for further cross validation of the calibrated annealing process temperature.

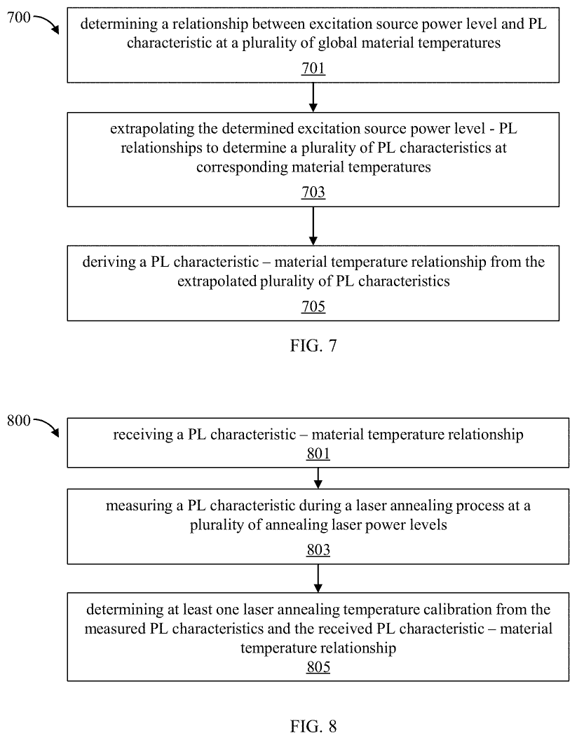

FIG. 7 illustrates an example method 700 of developing an annealing laser temperature calibration curve according to the present disclosure. In the illustrated example, at block 701, the method may include determining a relationship between excitation source power level and a PL characteristic such as PL peak wavelength at a plurality of global wafer temperatures. In an example, block 701 may be performed with a system such as system 100 that includes an excitation source, such as excitation source 10, and a PL spectrometer and associated optical components, such as spectrometer 150 and microscope 102 for analyzing a PL spectra of a wafer. PL peak wavelength versus excitation source power level curves 302 (FIG. 3) are an example of the determined relationship between excitation source power level and PL characteristic that may be obtained at block 701.

In block 703, method 700 may include extrapolating the determined excitation source power level—PL relationships to determine a plurality of PL characteristics at corresponding wafer temperatures. Y-axis intercepts 304 (FIG. 3) are an example of the PL characteristics at corresponding wafer temperatures that may be obtained at block 703. In an example, block 703 may be utilized to factor out or eliminate the influence of a local heating effect by the excitation source on the semiconductor material to infer or determine a PL characteristic at a particular global wafer temperature.

In block 705, method 700 may include deriving a PL characteristic-wafer temperature relationship from the extrapolated plurality of PL characteristics. Curve 402 (FIG. 4) is an example of a PL characteristic-wafer temperature relationship that may be obtained at block 705. As will be appreciated by persons having ordinary skill in the art, the PL characteristic-material temperature relationship can be extremely useful for accurately determining a local temperature of a semiconductor material from a spectral analysis of a PL emission from the material.

FIG. 8 illustrates an example method 800 of determining laser annealing temperature calibration for process temperature control during a laser annealing process. In the illustrated example, at block 801, the method may include receiving a PL characteristic-material temperature relationship for a particular wafer material of interest. In an example, the received PL characteristic-material temperature relationship is the one derived in block 705 of method 700. In other examples, the PL characteristic-material temperature relationship may be obtained from another source or method. In an example, the PL characteristic-material temperature relationship enables the accurate determination of a local wafer temperature from PL spectra that are captured during a laser annealing process.

In block 803, method 800 may include measuring a PL characteristic during a laser annealing process at a plurality of annealing laser power levels. The PL spectra illustrated in FIG. 5 are an example of the PL measurements that may be obtained at block 803 and the PL peak wavelengths 502 are an example of the recited PL characteristic. As described herein, in some examples, the PL characteristic may be a characteristic instead of or in addition to PL peak wavelength, such as PL intensity and/or PL FWHM. At block 805, method 800 may include determining at least one laser annealing temperature calibration from the measured PL characteristics obtained at block 803 and the received PL characteristic-material temperature relationship. Laser annealing temperature calibration curve 602 (FIG. 6) is an example of the at least one laser annealing temperature calibration that may be determined at block 805.

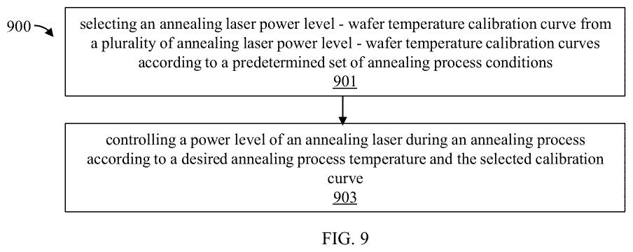

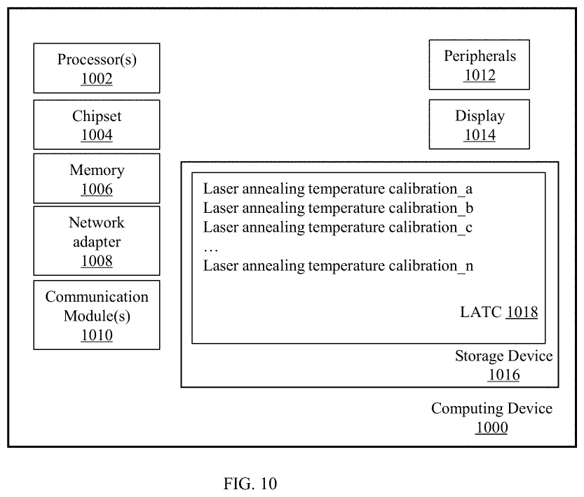

FIG. 9 illustrates an example method 900 for controlling an operating parameter, such as power level, of an annealing laser during an annealing process, such as an LSA process. In the illustrated example, at block 901, method 900 may include selecting, accessing, or receiving a laser annealing temperature calibration from a plurality of laser annealing temperature calibrations (such as laser annealing temperature calibrations 1018 (FIG. 10)) according to a predetermined set of annealing process conditions. The laser annealing temperature calibration determined in block 805 of FIG. 8 is an example of a laser annealing temperature calibration that may be selected at block 901. The laser annealing temperature calibration may be implemented in a variety of forms such as in the form of a curve or table (also referred to as a lookup table) or other means of translating a given operating parameter of an annealing laser to a local wafer temperature under a set of known and predefined annealing process parameters.

In an example, the selection may depend on identifying a plurality of annealing process parameters, such as one or more of a wafer material type, a chuck heater temperature, a wafer stage speed, a dwell time, and in some examples, a preheat laser power level, for a desired annealing process. Block 901 may include selecting a laser annealing temperature calibration from a plurality of laser annealing temperature calibrations stored in a computer storage device that corresponds to the identified plurality of annealing process parameters. At block 903, the method may include controlling a power level of an annealing laser during an annealing process according to a desired annealing process temperature or temperature profile and the selected calibration curve. The selected calibration may, therefore, be utilized by a controller, such as process controller 160 (FIG. 1) in a closed feedback loop to control an operating parameter of the annealing laser system 20 according to a target annealing temperature or temperature profile for a given annealing process. Block 903 results in the accurate and nearly instantaneous control of process temperature during an annealing process, such as a high speed LSA process by utilizing the selected laser annealing temperature calibration that was derived from PL measurements using the teachings of the present disclosure.

In some examples, methods 800 and 900 are performed for lower-temperature annealing processes, such as annealing processes where the wafer is heated to temperatures below 1000° C. and in some examples, temperatures below a melting point of the wafer material. One reason methods 800 and 900 can be more useful at temperatures below 1000° C. is because at higher temperatures thermal emission from the wafer surface begins to increase and influence the PL signal (e.g. PL signal 32), making it more challenging to differentiate and analyze the PL signal. In other examples, however, PL spectra may be utilized for higher temperature annealing, for example, annealing processes at temperatures in the range of 1000° C.-2000° C. alone or in combination with other temperature measurement techniques known in the art.

FIG. 10 is a block diagram illustrating physical components of one example implementation of computing device 1000 that may be utilized for one or both of process controller 160 and stage controller 80 (FIG. 1). Illustrated are at least one processor 1002 coupled to a chipset 1004. Also coupled to the chipset 1004 are a memory 1006, a network adapter 1008, and communication module(s) 1010. Peripherals 1012 and display 1014 are coupled to the computing device 1000. In another embodiment, the memory 1006 is coupled directly to the processor 1002. A storage device 1016 is also coupled to the chipset 1004.

Storage device 1016 may be any non-transitory computer-readable storage medium, such as a hard drive, compact disk read-only memory (CD-ROM), DVD, or a solid-state memory device. Storage device 1016 may contain any software or data that may be stored in computer storage in communication with a LSA system as is known in the art of LSA systems. As shown in FIG. 10, storage device 1016 also contains laser annealing calibrations (LATC) 1018 which includes a plurality of laser annealing calibrations_a-laser annealing calibrations_n for correlating annealing laser operating parameters to wafer temperature under a given set of predefined annealing process parameters as described herein. The_a-_n indicating a plurality of separate LATCs for corresponding set of annealing process conditions. The memory 1006 holds instructions and data used by the processor 1002. Network adapter 1008 couples the computing device 1000 to a local or wide area network and communication modules 1010 provide additional channels for wired or wireless communication.

As is known in the art, computing device 1000 can have different and/or other components than those shown in FIG. 10. In addition, computing device 1000 can lack certain illustrated components. In some examples the storage device 1016 can be local and/or remote from computing device 1000, such as a separate storage device, cold storage device, a storage area network (SAN), or a cloud-based storage architecture.

As is known in the art, computing device 1000 is adapted to execute computer program modules for providing functionality described herein. As used herein, the term “module” refers to computer program logic utilized to provide the specified functionality. Thus, a module can be implemented in hardware, firmware, and/or software. In one embodiment, program modules are stored on the storage device 1016, loaded into the memory 1006, and executed by the processor 1002.

Some portions of the above description describe the embodiments in terms of algorithmic processes or operations. These algorithmic descriptions and representations are commonly used by those skilled in the data processing arts to convey the substance of their work effectively to others skilled in the art. These operations, while described functionally, computationally, or logically, are understood to be implemented by computer programs comprising instructions for execution by a processor or equivalent electrical circuits, microcode, or the like. Furthermore, it has also proven convenient at times, to refer to these arrangements of functional operations as modules, without loss of generality.

While FIG. 10 illustrates a single computing device 1000 and storage device 1016, it will be understood that the functionality and storage provided by the computing device 1000 and storage device 1016 may be implemented in any number of computing devices and storage devices. By way of example, a first computing device 1000 may be used to implement process controller 160 and one or more other computing devices 1000 may be used to execute other functionality disclosed herein such as stage controller 80, chuck heater 70, etc.

Computing device 1000 may be configured to communicate with other computing devices of system 100 over one or more networks which may comprise any combination of local area and/or wide area networks, using both wired and/or wireless communication systems. In one embodiment, the network uses standard communications technologies and/or protocols. For example, the network includes communication links using technologies such as Ethernet, 802.11, worldwide interoperability for microwave access (WiMAX), 3G, 4G, code division multiple access (CDMA), digital subscriber line (DSL), etc. Examples of networking protocols used for communicating via the network include multiprotocol label switching (MPLS), transmission control protocol/Internet protocol (TCP/IP), hypertext transport protocol (HTTP), simple mail transfer protocol (SMTP), and file transfer protocol (FTP). Data exchanged over the network may be represented using any suitable format, such as hypertext markup language (HTML) or extensible markup language (XML). Those skilled in the art will recognize that encryption using other suitable techniques will be appropriate for various applications based on the nature of the network.

In some examples, methods of the present disclosure may include: determine a photoluminescence (PL)-temperature relationship for a wafer material; wherein the determining includes obtaining PL measurements at a plurality of wafer temperatures; wherein the plurality of wafer temperatures are obtained by heating the wafer material to a uniform temperature; wherein heating the wafer material to a uniform temperature includes heating the wafer with a chuck heater.

In some examples, the determining further includes determining PL-excitation source power level relationships at one or more of the plurality of temperatures; wherein the determining PL-excitation source power level relationships includes obtaining PL measurements at a plurality of excitation source power levels at each of the plurality of wafer temperatures.

In some examples, the determining includes determining a PL-temperature relationship that is independent of the excitation source power level; determining a PL characteristic at a zero power level for the excitation source from the PL-excitation source power level relationships; extrapolating to a zero power level from the PL-excitation source power level relationship; identifying a plurality of y-axis intercepts of a corresponding plurality of PL-excitation source power level relationships at a plurality of wafer material temperatures; or generating a PL temperature relationship that is independent of excitation source power level from the plurality of y-axis intercepts.

In some examples, utilizing the PL-temperature relationship to determine a local temperature of a wafer material during a LSA process, and in some examples, generating an annealing laser power-temperature relationship during a LSA calibration process that includes heating the wafer with an excitation source at a first excitation source power level; heating the wafer with the annealing laser at a second power level; determining a PL characteristic; determining the local temperature from the PL characteristic and PL-temperature relationship; and performing the foregoing at a plurality of annealing laser power levels to determine the annealing laser power-temperature relationship.

In some examples, heating the wafer with an excitation source at a first excitation source power level includes simultaneously using the excitation source as a preheat laser of a LSA process and as an excitation source for obtaining the PL characteristic; performing an LSA operation; measuring a PL characteristic during the LSA operation; controlling the annealing laser power according to the measured PL characteristic and a predetermined PL characteristic-temperature relationship.

The foregoing has been a detailed description of illustrative embodiments of the disclosure. It is noted that in the present specification and claims appended hereto, conjunctive language such as is used in the phrases “at least one of X, Y and Z” and “one or more of X, Y, and Z,” unless specifically stated or indicated otherwise, shall be taken to mean that each item in the conjunctive list can be present in any number exclusive of every other item in the list or in any number in combination with any or all other item(s) in the conjunctive list, each of which may also be present in any number. Applying this general rule, the conjunctive phrases in the foregoing examples in which the conjunctive list consists of X, Y, and Z shall each encompass: one or more of X; one or more of Y; one or more of Z; one or more of X and one or more of Y; one or more of Y and one or more of Z; one or more of X and one or more of Z; and one or more of X, one or more of Y and one or more of Z.

Various modifications and additions can be made without departing from the spirit and scope of this disclosure. Features of each of the various embodiments described above may be combined with features of other described embodiments as appropriate in order to provide a multiplicity of feature combinations in associated new embodiments. Furthermore, while the foregoing describes a number of separate embodiments, what has been described herein is merely illustrative of the application of the principles of the present disclosure. Additionally, although particular methods herein may be illustrated and/or described as being performed in a specific order, the ordering is highly variable within ordinary skill to achieve aspects of the present disclosure. Accordingly, this description is meant to be taken only by way of example, and not to otherwise limit the scope of this disclosure.

What is claimed is:

1. A method of determining a relationship between a photoluminescence (PL) spectra and a material temperature of a semiconductor material, the method comprising:
heating the semiconductor material to a plurality of temperatures;
exciting a PL response from the semiconductor material with an excitation source;
determining a PL characteristic from a PL signal emitted from the semiconductor material;
determining a relationship between a power level of the excitation source and the determined PL characteristic at each of the plurality of temperatures;
extrapolating the determined relationships to identify extrapolated PL characteristics for each of the plurality of temperatures at a zero power level condition of the excitation source to eliminate a local heating influence of the excitation source on the PL characteristic; and
deriving a PL characteristic-material temperature relationship from the plurality of extrapolated PL characteristics.

2. The method of claim 1, wherein the step of determining a relationship between a power level of the excitation source and the determined PL characteristic at each of the plurality of temperatures includes, for each of the plurality of temperatures, fitting a curve to PL characteristic data as a function of the power level of the excitation source, wherein the extrapolated plurality of PL characteristics are Y-axis intercept values of each of the fitted curves.

3. A method of determining a laser annealing temperature calibration for process temperature control, the method comprising:
receiving a photoluminescence (PL) characteristic-material temperature relationship for a semiconductor material;
measuring a PL characteristic during a laser annealing process of the semiconductor material at a plurality of annealing laser power levels; and
determining at least one laser annealing temperature calibration from the measured PL characteristics and the received PL characteristic-material temperature relationship.

4. The method of claim 3, wherein the laser annealing process is a dual wavelength laser spike annealing process performed by a preheat laser and the annealing laser.

5. The method of claim 4, wherein the step of measuring a PL characteristic includes utilizing the preheat laser as an excitation source for exciting a PL signal from the semiconductor material.

6. The method of claim 3, wherein the at least one laser annealing temperature calibration is a correlation between the annealing laser power level and an in-situ local temperature of the semiconductor material during a laser annealing process under a plurality of predetermined annealing process conditions.

7. The method of claim 6, wherein the plurality of annealing process conditions include a preheat laser power level, a chuck heater temperature, and a dwell time.

8. The method claim 3, wherein the received PL characteristic-material temperature relationship is the derived PL characteristic-material temperature relationship of claim 1.

9. A method for controlling an annealing laser operating parameter during a laser annealing process, the method comprising:
selecting, accessing, or receiving a laser annealing temperature calibration; and controlling an operating parameter of an annealing laser during an annealing process of a semiconductor material according to a target annealing process temperature and the laser annealing temperature calibration;
wherein the laser annealing temperature calibration is a correlation between the annealing laser operating parameter and an in-situ local temperature of the semiconductor material under a predetermined set of annealing process conditions, wherein the correlation was derived from photoluminescence measurements of the semiconductor material during a laser annealing process of the semiconductor material.

10. The method of claim 9, wherein the step of selecting, accessing, or receiving a laser annealing temperature calibration includes selecting, accessing, or receiving a laser annealing temperature calibration from a plurality of laser annealing temperature calibrations according to one or more annealing process conditions, wherein each of the plurality of laser annealing temperature calibrations are associated with a corresponding respective set of annealing process conditions.

11. The method of claim 10, wherein the set of annealing process conditions includes one or more of a preheat laser power level, a chuck heater temperature, and a dwell time.

12. The method of claim 9, wherein the annealing process is a low temperature annealing process, the target annealing process temperature is below about 1,000° C. or below a melting point of the semiconductor material.

13. A method of calibrating an annealing process temperature in a laser annealing system that includes a first laser and an annealing laser, the method comprising:
forming an annealing image on a region of a semiconductor material with the annealing laser; optically exciting the region of the semiconductor material with the first laser to emit photoluminescence (PL) from the semiconductor material; and
spectrally resolving the PL to identify a PL characteristic that is dependent on a bandgap of the semiconductor material.

14. The method of claim 13, further comprising deriving an annealing temperature calibration from the PL characteristic and a temperature dependency of the PL characteristic.

15. The method of claim 13, wherein the laser annealing system is a dual wavelength laser spike annealing system and the first laser is designed and configured as a preheat laser.

16. The method of claim 15, wherein the first laser emits a near infrared wavelength beam and forms a first image on the semiconductor material and the annealing laser emits a long wavelength infrared beam that is designed to form a second image that overlaps and is smaller than the first image.

17. A method for controlling an annealing laser operating parameter during a laser annealing process, the method comprising:
controlling an operating parameter of an annealing laser during an annealing process of a semiconductor material according to a target annealing process temperature and a laser annealing temperature calibration that was created by performing the method of claim 13.
